(19) United States
(12) Patent Application Publication
(10) Pub. No.: US 2007/0096826 A1
(43) Pub. Date: May 3, 2007

(54) Methods and system of feedback in amplifier circuit

(76) Inventor: Lowell E. Kolb, Loveland, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/260,119

(22) Filed: Oct. 27, 2005

(51) Int. Cl. H03F 1/34

(52) U.S. Cl. 330/294

(57) ABSTRACT

A method and system for providing feedback in an amplifier circuit. At least some of the illustrative embodiments are a method comprising providing feedback to a base of a transistor of an emitter-follower circuit, the providing proportional to both amplitude of a collector current and frequency of a collector current.

### BACKGROUND

Emitter-follower circuits are used in the electronics industry to drive high current loads. The emitter-follower circuits (which may also be referred to as common-collector circuits or source-follower circuits) have the characteristic of having close-to-unity gain, which enables such circuits to interface between relatively low-powered control circuits (e.g., voltages produced by digital-to-analog converters) and large current loads.

Emitter-follower circuits are particularly susceptible to instability in the presence of capacitive loads connected to their output terminals (emitters) which instability leads to oscillation. The problem is exacerbated if there exists inductance in series with the base of the transistor. If the emitter-follower circuit becomes unstable and oscillates, improper operation of the circuit, excessive radio frequency emissions from the product, or even damage to the devices or the circuits may occur.

### BRIEF DESCRIPTION OF THE DRAWINGS

For a detailed description of exemplary embodiments of the invention, reference will now be made to the accompanying drawings in which:

FIG. 1 shows an emitter-follower circuit in accordance with embodiments of the invention;

FIG. 2 shows a plurality of waveforms associated with an emitter-follower circuit in accordance with the embodiments of the invention;

FIG. 3 shows gain as a function of frequency for an illustrative emitter-follower circuit that does not utilize embodiments of the present invention;

FIG. 4 illustrates gain as a function of frequency for an emitter-follower circuit in accordance with the embodiments of the invention; and

FIG. 5 illustrates an emitter-follower circuit in accordance with alternative embodiments of the invention.

### NOTATION AND NOMENCLATURE

Certain terms are used throughout the following description and claims to refer to particular system components. As one skilled in the art will appreciate, electronics companies may refer to a component by different names. This document does not intend to distinguish between components that differ in name but not function.

In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct electrical connection, or through an indirect connection via other devices and connections.

The term “collector” in this specification and the claims shall refer to the collector terminal of a bipolar junction transistor, and shall also refer to the drain terminal of a field-effect transistor (FET) and the family of related transistors. Thus, reference to a collector should not be construed as limiting the device to which the term refers to a bipolar junction transistor. Likewise, the term “base” shall refer to the base terminal of a bipolar junction transistor, and also shall refer to the gate terminal of a FET. Finally, the term “emitter” shall refer to the emitter terminal of a bipolar junction transistor, and also shall refer to the source terminal of a FET.

The terms “emitter-follower circuit,” “source-follower circuit,” or “common-collector circuit” in this specification and in the claims refers to amplifier circuits having unity voltage gain or less, and having greater than unity current gain.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure. In addition, one skilled in the art will understand that the following description has broad application, and the discussion of any embodiment is meant only to be exemplary of that embodiment, and not intended to intimate that the scope of the disclosure is limited to that embodiment.

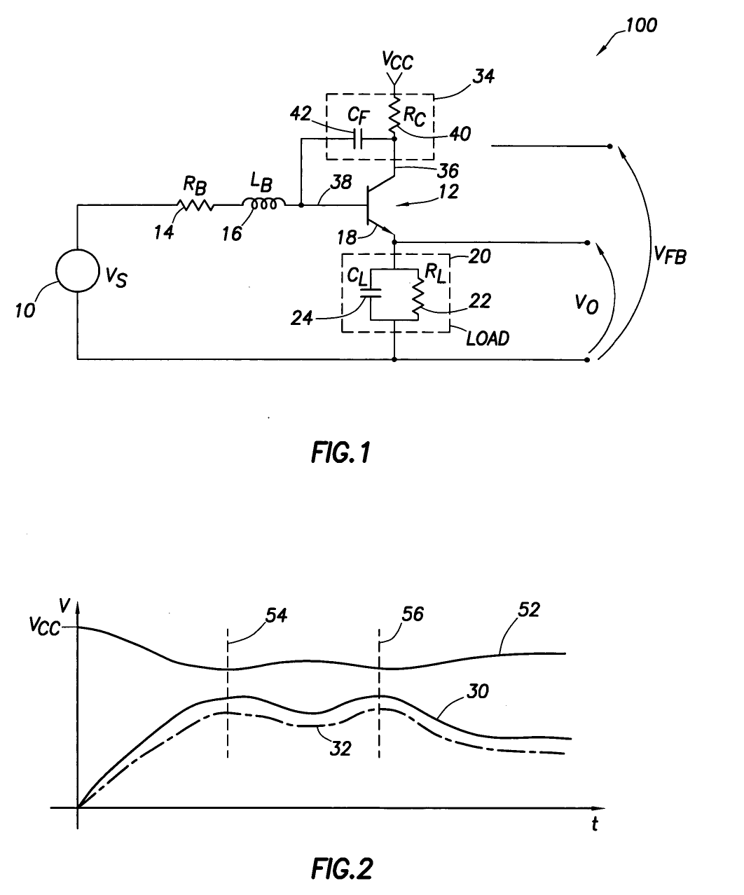

FIG. 1 illustrates an emitter-follower circuit 100 in accordance with embodiments of the invention. In particular, FIG. 1 illustrates a signal or control voltage source (Vₛ) 10 coupled to the base 38 of a transistor 12. The control voltage source 10 may be any suitable source for providing a signal to the emitter-follower circuit 100 (e.g., an analog signal created by a digital-to-analog (DA) converter). FIG. 1 shows transistor 12 to be a bipolar junction transistor, and in particular an n-p-n bipolar transistor; however, using a bipolar junction transistor is only illustrative, and the systems and related methods described in this specification are equally applicable to other transistors, such as field-effect transistors (FETS).

In some embodiments, the control voltage source 10 couples to the base 38 by way of a base resistor (R_{B}) 14 and optionally a base inductor (L_{B}) 16. The base resistor 14 and base inductor 16 may each be individual circuit components, or either or both of these may be parasitic (i.e., caused by degradation and/or imperfection of connections within the transistor). The emitter 18 of the transistor 12 couples to a load 20, which load may take many forms (e.g., a motor optionally coupled to a fan, a relay, a solenoid, or heaters). For purposes of illustration, load 20 is shown to have a load resistance (R_{L}) 22 and a load capacitance (C_{L}) 24, although any circuit element may be present in the load.

Emitter-follower circuits 100 in accordance with the embodiments of the invention exhibit the characteristic of having slightly less than unity gain. FIG. 2 shows a graph as a function of time of the voltage of an illustrative signal 30 provided by the control voltage source 10 to the transistor 12. FIG. 2 also shows an illustrative output voltage of the emitter-follower circuit 100 as a function of time co-plotted with the line 30. In particular, line 32 (dash-dot-dash) shows the output voltage (V_{O}) signal which may be seen at the output terminal (emitter) of the emitter-follower circuit 100 given the control signal 30. As illustrated in FIG. 2, the voltage of the output voltage signal 32 is slightly less than the voltage of the signal provided by the control voltage source 10. While there is little if any voltage gain, the advantage of an emitter-follower circuit is its large current gain. Thus, while the voltage source 10 may only be capable of sourcing a few tens of milli-amps, the emitter-follower circuit 100 may be capable of sourcing current sufficient to drive high current devices (e.g., motors, relays, and solenoids).

Emitter-follower circuits are susceptible to instability based on the interplay of base inductance 16 with load capacitance 24. Consider for purposes of explanation the emitter-follower circuit 100 without the feedback circuit 34 (the feedback circuit 34 is discussed below). Stated otherwise, consider a situation where the supply voltage (V_{CC}) couples directly to the collector 36, and there is no external connection between the collector 36 and the base 38. In such a situation, and in the presence of base inductance 16 and load capacitance 24, the voltage gain as a function of frequency may be as illustrated in FIG. 3. The asymptotic response of the voltage gain at frequency F₁ is illustrative of a frequency at which the emitter-follower circuit is unstable. A circuit having an instability point such as this tends to oscillate, even if the signal provided by the control voltage source 10 is not sinusoidal in nature.

Returning again to FIG. 1, the inventor of the present specification has found that the instability in a emitter-follower circuit can be reduced by providing a negative or degenerative rate feedback to the base 38 of the transistor 12. More particularly, the inventor of the present specification has found that providing a feedback whose amplitude increases with frequency (rate feedback) based on the current in the collector 36 produces a decreasing emitter-follower circuit 100 gain as a function of increasing frequency. Stated otherwise, various embodiments provide a feedback to the base of the transistor of the emitter-follower circuit with the feedback proportional to both the amplitude of the collector current and frequency of the collector current. Inasmuch as the current in the collector 36 (as well as the voltage) is approximately 180 degrees out of phase with respect to the control voltage source 10, coupling a feedback proportional to the collector current to the base 38 is a degenerative or negative feedback which tends to cancel a portion of the signal of the control voltage source 10, thus reducing the effective gain of the emitter-follower circuit 100.

At least some embodiments provide the negative rate feedback by way of a feedback circuit 34. In accordance with these embodiments, feedback circuit 34 comprises a collector resistor (R_{C}) 40 (coupled between the supply voltage (V_{CC}) and the collector 36), and a feedback capacitor (C_{F}) 42. The resistance of collector resistor 40 is relatively small (guidelines for selecting values of the collector resistor 40, feedback capacitor 42 and base resistor 14 are discussed below) and thus current in the collector 36 creates a feedback voltage (V_{FB}) at the collector 36 which is proportional to the current in the collector 36.

FIG. 2 illustrates the feedback voltage 52 at the collector 36 with the collector resistor in place and the control voltage source 10 providing the illustrative control signal 30. In particular, feedback voltage 52 created by the presence of the collector resistor has the same frequency as the control signal 30 from the control voltage source 10. The feedback voltage, however, is 180 degrees out of phase with respect to the control signal 30 from the control voltage source, and the peak-to-peak amplitude of similar features, (e.g., between the peak 54 and peak 56 of signal 30) are smaller. In these embodiments, the feedback voltage created by the presence of the collector resistor 40 couples to the base 38 through the feedback capacitor 42, which, from an impedance standpoint, decreases in impedance as the frequency increases.

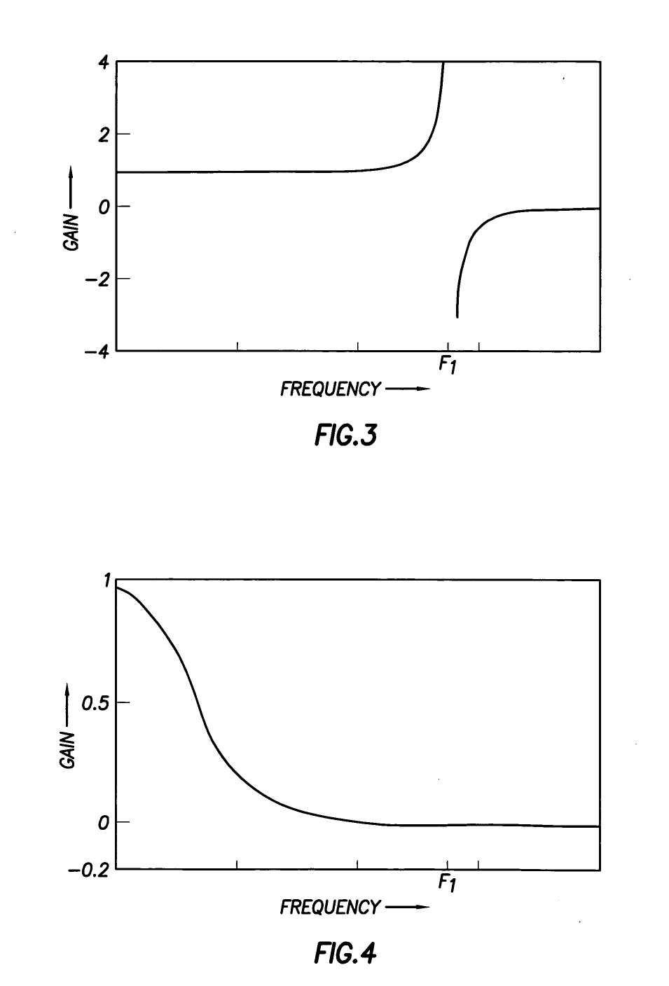

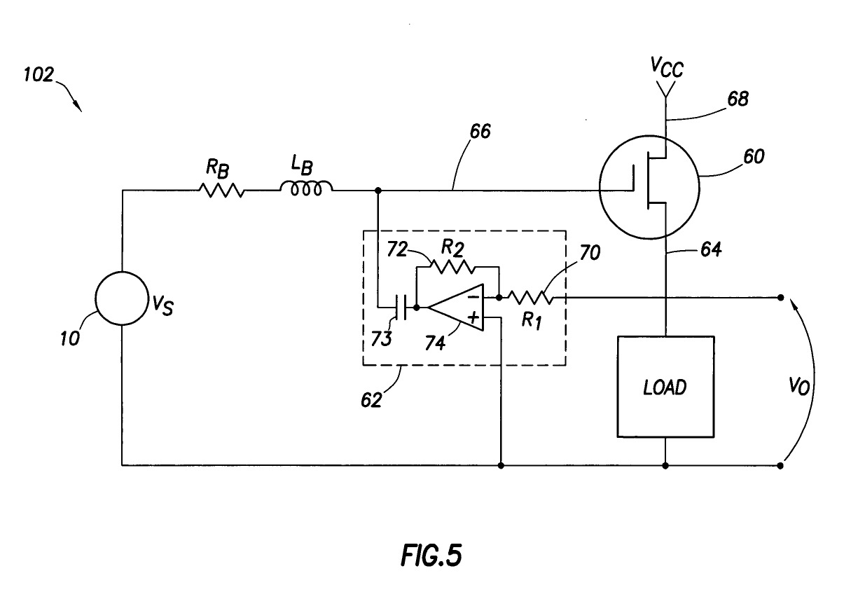

FIG. 4 shows voltage gain as a function of frequency for an emitter-follower circuit 100 having components and values similar to those whose gain is illustrated by FIG. 3, but utilizing a negative rate feedback circuit 34 in accordance with the embodiments of the invention. In particular, FIG. 4 shows that because of the feedback proportional to both the amplitude of the collector current and frequency of the collector current, the gain falls off with increasing frequency such that at the frequency where the circuit previously went unstable, F₁, no instability is present.

The discussion now turns to selecting values of various components for proper operation of the negative rate feedback in accordance with the embodiments of the invention. It is first noted that the base resistor 14 is not required, although there will be in most instances parasitic resistance present (and this could be considered some or all the base resistor). A base resistor 14 may be used in situations where the impedance of the voltage source 10 is lower than the inherent base resistance of the transistor 12 at nominal operating current. Thus, the resistance of the base resistor is chosen such that the source impedance (Z_{S}) considered with resistance of the base resistor 14 (Z_{S+}R_{B}) is greater than or equal to the inherent base resistance of the transistor, which may be referred to in product specifications for bipolar junction transistors as re.

With respect to the selection of the collector resistor 40, increasing collector resistance decreases emitter-follower circuit dynamic range, and thus lower resistance values are better from a peak-to-peak output voltage perspective. However, the greater the resistance of the collector resistor 40, the greater the amplitude of the feedback voltage. In accordance with the embodiments of the invention, the emitter-follower circuit should be stable when the source impedance Z_{S} summed with the resistance of the base R_{B} (if present) is greater than the collector resistance R_{C}, and the sum of the source impedance Z_{S} and the resistance of the base R_{B} multiplied by the capacitance of the feedback capacitor C_{F} is greater than or equal to approximately four times the product of the collector resistance R_{C} and the load capacitance C_{L}. More particularly with respect to the first relationship, the sum of the source impedance Z_{S} and the resistance of the base R_{B} should be approximately ten times or more than resistance of the collector resistor.

In more mathematical terms then, when:
(Z_{S}+R_{B})>>R_{C} (1)
where Z_{S} is the source impedance, R_{B} is the base resistance (if any), and R_{C} is the collector resistance, then stability is conservatively ensured when:
C_{F}·(Z_{S}+R_{B})≧4·R_{C}·C_{L} (2)
where Z_{S}, R_{B}, and R_{C} are as above, C_{F} is the feedback capacitance and C_{L} is the load capacitance.

The various embodiments discussed to this point use a bipolar junction transistor and a feedback circuit coupled between the collector and the base. FIG. 5 illustrates an emitter-follower circuit 102 in accordance with alternative embodiments of the invention. In particular, FIG. 5 illustrates that in alternative embodiments of the invention, rather than using a bipolar junction transistor, a FET 60 may be used. In such a situation, the emitter may be equivalently referred to as the “source,” the collector equivalently referred to as the “drain,” and the base equivalently referred to as the “gate.” Moreover, FIG. 5 illustrates an alternative feedback circuit 62 that may be used with either a bipolar junction transistor or a FET, and this alternative feedback circuit 62 couples between the emitter (source) 64 and the base (gate) 66. Because the voltage at the emitter (source) 64 in an emitter-follower circuit is in phase with the signal produced by the control voltage source 10, in order to provide negative feedback the illustrative feedback circuit 62 preferably generates an output signal that is an inverted version of the output voltage (V_{O}) prior to coupling the output signal to the base (gate) 66. The illustrative embodiments of FIG. 5 show such a circuit in the form of an operational amplifier configured as an inverting amplifier. However, the operational amplifier is illustrative of any inverting amplifier circuit (e.g., inverting amplifier made from individual components such as resistors and transistors). The gain of the amplifier in the feedback circuit 62 in accordance with these alternative embodiments is preferably selected to mimic a voltage that may be generated by coupling a collector resistor between the power rail source and the collector (drain) 68 (see, e.g., feedback voltage 52 of FIG. 2). Thus, the values for the resistor (R₁) 70 and the feedback resistor (R₂) 72 in feedback circuit 42 should thus be chosen to mimic a feedback voltage signal as discussed with respect to the feedback circuit 34 of FIG. 1. Feedback circuit 42 further comprises a feedback capacitor 72 that couples the output signal of the illustrative operational amplifier 74 to the base (gate) 66.

Thus, FIG. 5 illustrates that the negative rate feedback related to the current in the collector (drain) need not be generated on the collector (drain) side of the amplifier, and instead may be generated proportional to the output voltage as illustrated in FIG. 5 using an inverting amplifier. In yet still further embodiments, the current within the collector (drain) may be sensed by other methods such as Hall effect devices or current transformers.

The above discussion is meant to be illustrative of the principles and various embodiments of the present invention. Numerous variations and modifications will become apparent to those skilled in the art once the above disclosure is fully appreciated. For example, the embodiments of illustrative FIG. 1 show the use of an external feedback capacitor 42 as a part of the feedback circuit 34. In alternative embodiments of the invention the transistor 12 and/or FET 60 may be selected such as the inherent parasitic capacitance between the collector (drain) and the base (gate) is sufficient to fulfill the purposes of the feedback capacitor 42, and in these cases a separate feedback capacitor 42 may be omitted.

What is claimed is:

1. A method comprising providing feedback to a base of a transistor of an emitter-follower circuit, the providing proportional to both amplitude of a collector current and frequency of the collector current.

2. The method as defined in claim 1 wherein providing further comprises providing the feedback from the collector of the transistor to a base of the transistor.

3. The method as defined in claim 2 wherein providing further comprises coupling the collector, which collector couples to a voltage source through a collector resistor, to the base by way of a capacitor.

4. The method as defined in claim 3 wherein coupling further comprises coupling the collector wherein an impedance of a signal source coupled to the base summed with resistance of a base resistor is greater than the resistance of the collector resistor, and wherein the sum of the impedance of the signal source and the resistance of the base resistor multiplied by capacitance of the capacitor is greater than or equal to approximately four times the product of the resistance of the collector resistor and the capacitance of a load.

5. The method as defined in claim 1 wherein providing further comprises providing the feedback based on the amplitude of an emitter voltage and the frequency of the emitter voltage, wherein the amplitude and frequency of the emitter voltage are proportional to the amplitude and frequency of the collector current.

6. A system comprising:
a signal source providing a signal;
a transistor having a base, emitter and collector, the collector coupled to a supply voltage source and the base coupled to the signal source;
a load coupled to the emitter; and
a feedback circuit coupled to the base, the feedback circuit provides a feedback signal to the base proportional to both the amplitude and frequency of current at the collector;
wherein a peak-to-peak voltage of the signal provided by the signal source to the base resistor is greater than a peak-to-peak voltage of a signal in the collector.

7. The system as defined in claim 6 wherein the feedback circuit further comprises a collector resistor coupled between the collector and the voltage source.

8. The system as defined in claim 7 wherein an impedance of the signal source is greater than the resistance of the collector resistor, and wherein the impedance of the signal source multiplied by capacitance of the feedback capacitor is greater than or equal to approximately four times the product of the resistance of the collector resistor and a capacitance of the load.

9. The system as defined in claim 6 wherein the feedback circuit further comprises a feedback capacitor coupled between the collector and the base.

10. The system, as defined in claim 6 further comprising a base resistor coupled between the signal source and the base of the transistor, wherein resistance of the base resistor added to the impedance of the signal source is greater than or equal to inherent base resistance of the transistor.

11. The system as defined in claim 10 wherein an impedance of the signal source summed with resistance of the base resistor is greater than the resistance of a collector resistor, and wherein the sum of the impedance of the signal source and the resistance of the base resistor multiplied by capacitance of the feedback capacitor is greater than or equal to approximately four times the product of the resistance of the collector resistor and the capacitance of the load.

12. The system as defined in claim 6 wherein the feedback circuit is also coupled to the emitter, the feedback circuit provides the feedback signal to the base inversely proportional to the voltage of a signal at the emitter and proportional to the frequency of the signal at the emitter.

13. The system as defined in claim 6 wherein the feedback circuit further comprises:
a collector resistor coupled between the collector and the voltage source;
wherein an impedance of the signal source summed with resistance of a base resistor, if present, is greater than the resistance of the collector resistor, and wherein the sum of the impedance of the signal source and the resistance of the base resistor, if present, multiplied by capacitance of collector-base parasitic capacitance is greater than or equal to approximately four times the product of the resistance of the collector resistor and capacitance of the load.

14. The system as defined in claim 6 wherein the transistor comprises a bipolar-junction transistor.

15. The system as defined in claim 6 wherein the transistor comprises a field effect transistor.

16. The system as defined in claim 6 wherein the load is one selected from the group: electrical motor; a relay; and a solenoid.

17. The system as defined in claim 6 wherein the load is a direct current (DC) motor coupled to a fan.

18. A system comprising:
a means for providing a signal;
a means for amplifying having a base connection means, an emitter connection means, and a collector connection means, the collector connection means coupled to a supply voltage source means, and the base connection means coupled to the means for providing;
a means for utilizing electrical energy coupled to the emitter connection means; and
a means for providing feedback to the base connection means, the feedback proportional to amplitude and frequency of electrical current at the collector connection means;
wherein the signal gain as between the means for providing and the means for utilizing is substantially unity.

19. The system as defined in claim 18 wherein the means for amplifying is one selected from the group: a bipolar junction transistor; and a field effect transistor.

20. The system as defined in claim 18 wherein the means for providing feedback further comprises a means for providing feedback from the emitter connection means to the base connection means proportional to amplitude and frequency of electrical current at the collector connection means.
